(19) United States
(12) Patent Application Publication
(10) Pub. No.: US 2025/0364983 A1
(43) Pub. Date: Nov. 27, 2025

(54) SEMICONDUCTOR SWITCHING ELEMENT DRIVE CIRCUIT

(71) Applicant: Mitsubishi Electric Corporation, Tokyo (JP)

(72) Inventor: Koki SAMURA, Tokyo (JP)

(73) Assignee: Mitsubishi Electric Corporation, Tokyo (JP)

(21) Appl. No.: 18/872,184

(22) PCT Filed: Sep. 13, 2022
(86) PCT No.: PCT/JP2022/034156

§ 371 Date: Dec. 5, 2024

(51) Int. Cl. H03K 17/082; H03K 17/08

(52) U.S. Cl. CPC H03K 17/0828; H03K 2017/0806

(57) ABSTRACT

An object is to provide a technique that makes it possible to change a switching speed depending on a temperature. The semiconductor switching element drive circuit includes an output voltage detection unit that generates a switching signal based on a temperature related to a semiconductor switching element and an output voltage of the semiconductor switching element. The output voltage for generating the switching signal by the output voltage detection unit in a case where the temperature is a first temperature is larger than the output voltage for generating the switching signal by the output voltage detection unit in a case where the temperature is a second temperature lower than the first temperature.

### TECHNICAL FIELD

The present disclosure relates to a semiconductor switching element drive circuit.

### BACKGROUND ART

It is known that in a semiconductor switching element used in an inverter or the like, a switching loss and a surge voltage are generated during turn-off operation. There is a trade-off relationship between the switching loss and the surge voltage. When the switching loss decreases, the surge voltage increases, whereas when the surge voltage decreases, the switching loss increases.

As a technique for improving both the switching loss and the surge voltage during the turn-off operation, a technique called active gate drive has been proposed (for example, Patent Document 1). In the active gate drive, a switching speed is switched by switching a gate resistance value during turn-off operation of a semiconductor switching element.

### PRIOR ART DOCUMENT

### Patent Document

Patent Document 1: Japanese Patent No. 4991446

### SUMMARY

### Problem to be Solved by the Invention

In the conventional art, a timing of switching the switching speed during the turn-off operation is fixed regardless of a temperature concerning the semiconductor switching element. However, even if a switching timing of a gate resistance value is appropriately adjusted in a case where a junction temperature is an ordinary temperature, there is a problem that the switching loss may be deteriorated in a case where the junction temperature is high. Furthermore, in a case where the junction temperature is low, a withstand voltage of the semiconductor element generally decreases. Therefore, in a case where drive conditions are the same regardless of the junction temperature, there is a problem that the surge voltage may exceed the withstand voltage of the semiconductor element.

The present disclosure has been made in view of the above problems, and an object of the present disclosure is to provide a technique that makes it possible to change a switching speed depending on a temperature.

### Means to Solve the Problem

A semiconductor switching element drive circuit according to the present disclosure is a semiconductor switching element drive circuit that drives a gate of a semiconductor switching element and includes a control unit that switches a switching speed during turn-off operation of the semiconductor switching element based on a switching signal; and an output voltage detection unit that generates the switching signal based on a temperature related to the semiconductor switching element and an output voltage of the semiconductor switching element, and the output voltage for generating the switching signal by the output voltage detection unit in a case where the temperature is a first temperature is larger than the output voltage for generating the switching signal by the output voltage detection unit in a case where the temperature is a second temperature lower than the first temperature.

Objects, features, aspects, and advantages of the present disclosure will become more apparent from the following detailed description and the accompanying drawings.

### Effects of the Invention

According to the present disclosure, the output voltage detection unit generates a switching signal based on a temperature related to the semiconductor switching element and an output voltage of the semiconductor switching element, and the output voltage for generating the switching signal by the output voltage detection unit in a case where the temperature is a first temperature is larger than the output voltage for generating the switching signal by the output voltage detection unit in a case where the temperature is a second temperature lower than the first temperature. According to such a configuration, a switching speed can be changed depending on a temperature.

### BRIEF DESCRIPTION OF DRAWINGS

FIG. 1 is a circuit diagram illustrating a configuration of a semiconductor switching element drive circuit according to a first embodiment.

FIG. 2 is a diagram illustrating an example of a waveform during turn-off operation of a semiconductor switching element according to the first embodiment.

FIG. 3 is a circuit diagram illustrating a configuration of a semiconductor switching element drive circuit according to a second embodiment.

FIG. 4 is a circuit diagram illustrating a configuration of a semiconductor switching element drive circuit according to a third embodiment.

FIG. 5 is a circuit diagram illustrating a configuration of a semiconductor switching element drive circuit according to a fourth embodiment.

### DESCRIPTION OF EMBODIMENTS

Hereinafter, embodiments will be described with reference to the accompanying drawings. Features described in the following embodiments are examples, and not all features are essential. In the following description, similar constituent elements in a plurality of embodiments are given identical or similar reference signs, and different constituent elements will be mainly described.

### First Embodiment

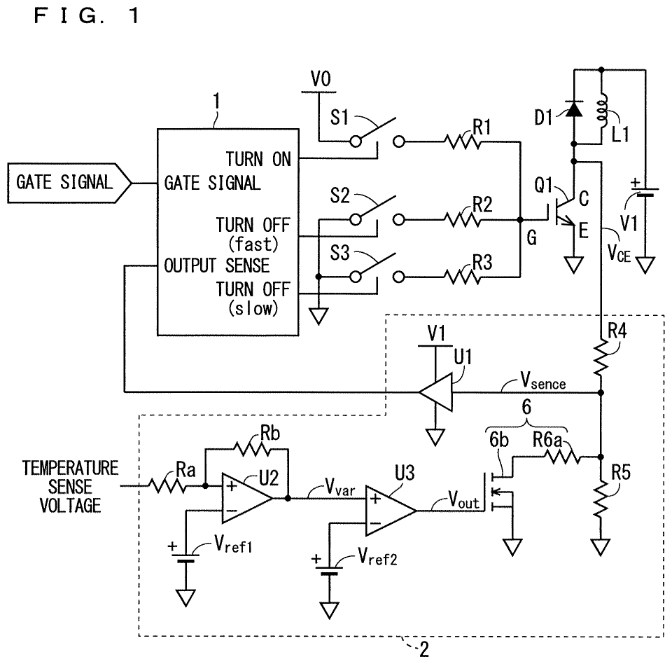

FIG. 1 is a circuit diagram illustrating a configuration of a semiconductor switching element drive circuit (hereinafter, sometimes abbreviated as a “drive circuit”) according to a first embodiment. The semiconductor switching element drive circuit drives a gate of a semiconductor switching element Q1. In the example of FIG. 1, the semiconductor switching element Q1 is an Insulated Gate Bipolar Transistor (IGBT), but may be a Reverse Conducting-IGBT (RC-IGBT) or a Metal Oxide Semiconductor Field Effect Transistor (MOSFET). The semiconductor switching element Q1 may be made of normal silicon (Si) or may be made of a wide band gap semiconductor such as silicon carbide (SiC), gallium nitride (GaN), or diamond. In a case where the semiconductor switching element Q1 is made of a wide band gap semiconductor, it is possible to achieve stable operation at a high temperature and at a high voltage and to increase a switching speed.

A diode D1 and an inductive load L1 connected in parallel are connected between the semiconductor switching element Q1 and a power supply V1. The diode D1 has a function of freewheeling a load current when the semiconductor switching element Q1 is turned off. Power is supplied to the load L1 by the power supply V1.

The semiconductor switching element drive circuit according to the first embodiment includes a control unit 1, an output voltage detection unit 2, switches S1, S2, and S3, and gate resistors R1, R2, and R3.

The switch S1 and the gate resistor R1 are connected in series between a power supply V0 (for example, 15 V) and the gate of the semiconductor switching element Q1. The switch S2 and the gate resistor R2 are connected in series between a potential (for example, ground potential) lower than the power supply V0 and the gate of the semiconductor switching element Q1. Similarly, the switch S3 and the gate resistor R3 are connected in series between a potential (ground potential in FIG. 1) lower than the power supply V0 and the gate of the semiconductor switching element Q1. The switches S1, S2, and S3 may be, for example, semiconductor switching elements or may be other elements.

The control unit 1 controls on and off of the switches S1, S2, and S3 based on a gate signal. When the switch S1 is turned on and the switch S2 is turned off by the control unit 1, the gate of the semiconductor switching element Q1 is electrically connected to the power supply V0 and the gate resistor R1, and the semiconductor switching element Q1 is turned on. When the switch S2 or the switch S3 is turned on and the switch S1 is turned off by the control unit 1, the gate of the semiconductor switching element Q1 is electrically connected to the ground potential and the gate resistor R2 or the gate resistor R3, and the semiconductor switching element Q1 is turned off.

In the above configuration, a resistance value of the gate resistor R3 is larger than a resistance value of the gate resistor R2. Accordingly, a switching speed during turn-off operation in a case where the semiconductor switching element Q1 is connected to the gate resistor R3 is lower than a switching speed during turn-off operation in a case where the semiconductor switching element Q1 is connected to the gate resistor R2. Note that a switching speed during turn-off operation corresponds to a speed at which the semiconductor switching element Q1 changes from an on state to an off state.

The control unit 1 switches connection of the gate resistors R2 and R3 to the semiconductor switching element Q1 during the turn-off operation based on a switching signal from the output voltage detection unit 2, thereby switching the switching speed of the semiconductor switching element Q1 during the turn-off operation. The control unit 1 switches the switching speed from a high switching speed to a low switching speed by switching the gate resistor from the gate resistor R2 to the gate resistor R3 during the turn-off operation based on a switching signal (V_{high}) input to an output sense from the output voltage detection unit 2, which will be described later.

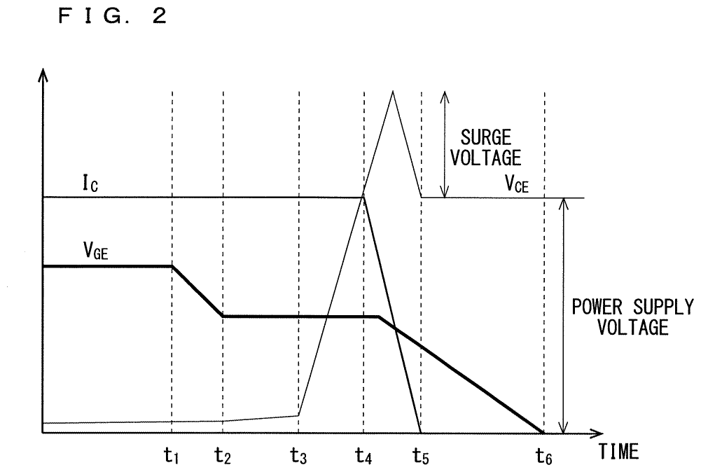

FIG. 2 is a diagram illustrating an example of a waveform during turn-off operation of the semiconductor switching element Q1. t₁ is a time point at which the gate signal is turned off and a gate voltage (V_{GE}) starts to decrease. t₂ is a time point at which an output voltage (V_{CE}), which is a collector voltage, starts to increase gradually and the gate voltage (V_{GE}) stops decreasing and becomes a constant voltage (Miller period voltage). t₃ is a time point at which the output voltage (V_{CE}) starts increasing rapidly. t₄ is a time point at which the output voltage (V_{CE}) reaches a power supply voltage and an output current (I_{C}) starts to decrease. t₅ is a time point at which the output current (I_{C}) becomes zero. t₆ is a time point at which the gate voltage (V_{GE}) becomes zero.

As illustrated in FIG. 2, during the turn-off operation of the semiconductor switching element Q1, the output voltage (V_{CE}) increases to the power supply voltage during the period t₃ to t₄, and the output current (I_{C}) decreases during the period t₄ to t₅. During the period t₃ to t₅ including these periods, a switching loss obtained by the output voltage x the output current occurs. On the other hand, during the period t₄ to t₅ in which the output current decreases, a surge voltage caused by parasitic inductance of an output current path such as the load L1 is generated in the output voltage (V_{CE}).

The switching loss is preferably low since the switching loss causes heat generation of the semiconductor switching element Q1 and the like. The surge voltage is preferably low since the sum of the surge voltage and the power supply voltage needs to be suppressed to be equal to or less than the withstand voltage of the semiconductor switching element Q1 or the like.

Here, when a resistance value of a gate resistor for turn-off is lowered, the switching speed during the turn-off operation of the semiconductor switching element Q1 increases, and the period t₃ to t₅ in FIG. 2 is shortened, and the switching loss decreases. However, since a change rate (ΔI_{C}/Δt) of the output current (I_{C}) of the semiconductor switching element Q1 in the period t₄ to t₅ in FIG. 2 increases, the surge voltage (=L×ΔI_{C}/Δt) generated by the parasitic inductance L of the output current path increases. Conversely, when the resistance value of the gate resistor for turn-off is increased, the surge voltage decreases, but the switching loss increases. As described above, the switching loss and the surge voltage are in a trade-off relationship.

However, if the control unit 1 decreases the gate resistance value to increase the switching speed before t₄ during the turn-off operation, the switching loss in the period t₃ to t₄ can be decreased. On the other hand, if the control unit 1 increases the gate resistance value to decrease the switching speed after t₄ during the turn-off operation, the surge voltage in the period t₄ to t₅ can be decreased. Therefore, a switching time point at which the switching speed is reduced is preferably t₄ in FIG. 2. Therefore, in the first embodiment, the output voltage detection unit 2 is configured to generate and output the switching signal (V_{high}) for switching the switching speed so that the switching time point at which the switching speed is reduced becomes t₄ in FIG. 2 as much as possible.

Next, the output voltage detection unit 2 will be described. As illustrated in FIG. 1, the output voltage detection unit 2 includes voltage-dividing resistors R4 and R5, a logic circuit U1, an operational amplifier U2, a comparator U3, and a change unit 6. The change unit 6 includes a resistor R6a and an N-type MOSFET 6b.

The voltage-dividing resistors R4 and R5 generate a divided voltage (Vₛₑₙₛₑ) of the output voltage (V_{CE}) of the semiconductor switching element Q1.

The logic circuit U1 is a circuit having a buffer function, and generates a switching signal based on the divided voltage (Vₛₑₙₛₑ) generated by the voltage-dividing resistors R4 and R5. In the first embodiment, the logic circuit U1 generates V_{high}, which is a switching signal for decreasing the switching speed, when the divided voltage (Vₛₑₙₛₑ) is larger than a predetermined threshold value, and generates V_{low} when the divided voltage (Vₛₑₙₛₑ) is smaller than the threshold value. The threshold value used in the logic circuit U1 concerning the divided voltage (Vₛₑₙₛₑ) is set by the power supply voltage (V1) supplied to the logic circuit U1. In the first embodiment, the power supply voltage of the logic circuit U1 is fixed to, for example, 5 V, and the threshold value used in the logic circuit U1 is fixed.

Note that, in a case where a delay time of the logic circuit U1 is shorter than a delay time of an analog comparator, the switching time point at which the switching speed is reduced can be easily adjusted to t₄ of FIG. 2.

According to the above configuration, by appropriately setting the threshold value used in the logic circuit U1 and appropriately setting the timing at which the switching signal (V_{high}) is generated and output by the output voltage detection unit 2, the switching time point for reducing the switching speed can be set to t₄ in FIG. 2. Therefore, it is possible to realize reduction of switching loss and reduction of a surge voltage which are in a trade-off relationship.

However, even if the switching timing of the gate resistance value is appropriately adjusted when a temperature related to the semiconductor switching element Q1 (hereinafter, also abbreviated as “switch temperature”) is an ordinary temperature, the switching loss may be deteriorated when the switch temperature is high. Furthermore, in a case where the switch temperature is low, a withstand voltage of the semiconductor element generally decreases. Therefore, in a case where drive conditions are the same regardless of the switch temperature, the surge voltage may undesirably exceed the withstand voltage of the semiconductor element. Note that the switch temperature is, for example, a junction temperature, a temperature detected by an on-chip temperature sense diode provided on the semiconductor switching element Q1, or a temperature detected by a thermistor provided on an insulating substrate of a semiconductor device including the semiconductor switching element Q1.

For the above reason, it is desirable that the timing of switching the gate resistance value, that is, the timing of decreasing the switching speed during the turn-off operation of the semiconductor switching element Q1 is changed depending on the switch temperature.

In consideration of the above, the output voltage detection unit 2 of the first embodiment is configured to generate the switching signal (V_{high}) based on the switch temperature and the output voltage (V_{CE}) of the semiconductor switching element Q1. Thus, the semiconductor switching element drive circuit according to the first embodiment can appropriately change the timing of decreasing the switching speed based on the switch temperature. Remaining constituent elements of the output voltage detection unit 2 that can realize this will be described below.

A temperature sense voltage corresponding to the switch temperature and having negative temperature characteristics and a first reference voltage (V_{ref1}) are input to the operational amplifier U2. Since the temperature sense voltage has negative temperature characteristics, the temperature sense voltage decreases as the temperature increases. The operational amplifier U2 to which resistors Ra and Rb are connected constitutes an inverting amplifier circuit, and an output (Vᵥₐᵣ) of the operational amplifier U2 is expressed by the following formula (1) using the first reference voltage (V_{ref1}) and the temperature sense voltage (Vₛ). As the switch temperature increases, the temperature sense voltage (Vₛ) decreases, and therefore the output (Vᵥₐᵣ) of the operational amplifier U2 that inverts the input increases as can be seen from the following formula (1).

$$[ Mathematical formula 1 ]$$

$${V}_{var} = ( 1 + \frac{Rb}{Rb} ) {V}_{ref} - \frac{Rb}{Ra} {V}_{s} \qquad ( 1 )$$

The output (Vᵥₐᵣ) of the operational amplifier U2 and a second reference voltage (V_{ref2}) are input to the comparator U3. The comparator U3 outputs Vₒᵤₜ based on the output (Vᵥₐᵣ) of the operational amplifier U2 and the second reference voltage (V_{ref2}). In a case where the output (Vᵥₐᵣ) of the operational amplifier U2 is larger than a threshold value corresponding to the second reference voltage (V_{ref2}), the output (Vₒᵤₜ) of the comparator U3 is larger than an on-voltage of the MOSFET 6b. On the other hand, in a case where the output (Vᵥₐᵣ) of the operational amplifier U2 is smaller than the threshold value corresponding to the second reference voltage (V_{ref2}), the output (Vₒᵤₜ) of the comparator U3 is smaller than the on-voltage of the MOSFET 6b.

In the first embodiment, in a case where the switch temperature is a relatively high first temperature, the output (Vᵥₐᵣ) of the operational amplifier U2 becomes large, and the output (Vₒᵤₜ) of the comparator U3 becomes larger than the on-voltage of the MOSFET 6b. On the other hand, in a case where the switch temperature is a second temperature lower than the first temperature, the output (Vᵥₐᵣ) of the operational amplifier U2 becomes small, and the output (Vₒᵤₜ) of the comparator U3 becomes smaller than the on-voltage of the MOSFET 6b.

A gate of the MOSFET 6b is connected to the output (Vₒᵤₜ) of the comparator U3, a drain of the MOSFET 6b is connected to a connection point between the voltage-dividing resistor R4 and the voltage-dividing resistor R5 with the resistor R6a interposed therebetween, and a source of the MOSFET 6b is connected to the ground potential. A resistance value of the MOSFET 6b is smaller than the resistor R6a.

When the output (Vₒᵤₜ) of the comparator U3 smaller than the on-voltage is input to the gate of the MOSFET 6b, the MOSFET 6b is turned off, and therefore the voltage-dividing resistor R4 is not substantially connected to the resistor R6a and is connected to the voltage-dividing resistor R5. On the other hand, when the output (Vₒᵤₜ) of the comparator U3 larger than the on-voltage is input to the gate of the MOSFET 6b, the MOSFET 6b is turned on, and therefore the voltage-dividing resistor R4 is connected to a combined resistor of the voltage-dividing resistor R5 and the resistor R6a, which has a smaller resistance value than the voltage-dividing resistor R5. Since the change unit 6 includes the resistor R6a and the MOSFET 6b, it is possible to change the divided voltage (Vₛₑₙₛₑ) by changing the resistance values of the voltage-dividing resistors R4 and R5 based on the output (Vₒᵤₜ) of the comparator U3.

In the first embodiment, in a case where the switch temperature is the relatively high first temperature, the output (Vₒᵤₜ) of the comparator U3 is larger than the on-voltage of the MOSFET 6b, and the voltage-dividing resistor R4 is connected to the combined resistor having a relatively small resistance value. On the other hand, in a case where the switch temperature is a second temperature lower than the first temperature, the output (Vₒᵤₜ) of the comparator U3 is smaller than the on-voltage of the MOSFET 6b, and the voltage-dividing resistor R4 is connected to the voltage-dividing resistor R5 having a relatively large resistance value.

As a result, regarding the output voltage (V_{CE}) of the semiconductor switching element Q1 in a case where the divided voltage (Vₛₑₙₛₑ) is equal to the threshold value of the logic circuit U1, the output voltage (V_{CE}) in a case where the switch temperature is the first temperature is larger than the output voltage (V_{CE}) in a case where the switch temperature is the second temperature. That is, the output voltage (V_{CE}) for generating the switching signal by the output voltage detection unit 2 in a case where the switch temperature is the first temperature is larger than the output voltage (V_{CE}) for generating the switching signal by the output voltage detection unit 2 in a case where the switch temperature is the second temperature.

### <Summary of First Embodiment>

According to the semiconductor switching element drive circuit of the first embodiment as described above, the output voltage detection unit 2 generates the switching signal based on the switch temperature and the output voltage (V_{CE}) of the semiconductor switching element Q1. The output voltage (V_{CE}) for generating the switching signal by the output voltage detection unit 2 in a case where the switch temperature is the first temperature is larger than the output voltage (V_{CE}) for generating the switching signal by the output voltage detection unit 2 in a case where the switch temperature is the second temperature. Here, as illustrated in FIG. 2, during the turn-off operation of the semiconductor switching element Q1, the output voltage (V_{CE}) of the semiconductor switching element Q1 increases with time, and the tendency is substantially the same regardless of the temperature (not illustrated). Therefore, the timing of decreasing the switching speed in a case where the switch temperature is the relatively high first temperature can be made later than the timing of decreasing the switching speed in a case where the switch temperature is the relatively low second temperature. That is, the switching speed can be changed depending on the switch temperature.

Therefore, it is possible to properly adjust a switching timing of the gate resistance value when the temperature related to the semiconductor switching element Q1 is an ordinary temperature, and properly adjust the timing when the temperature is high. In addition, it is possible to reduce the switching loss when the temperature related to the semiconductor switching element Q1 is an ordinary temperature and to reduce the surge voltage when the temperature is low.

### Second Embodiment

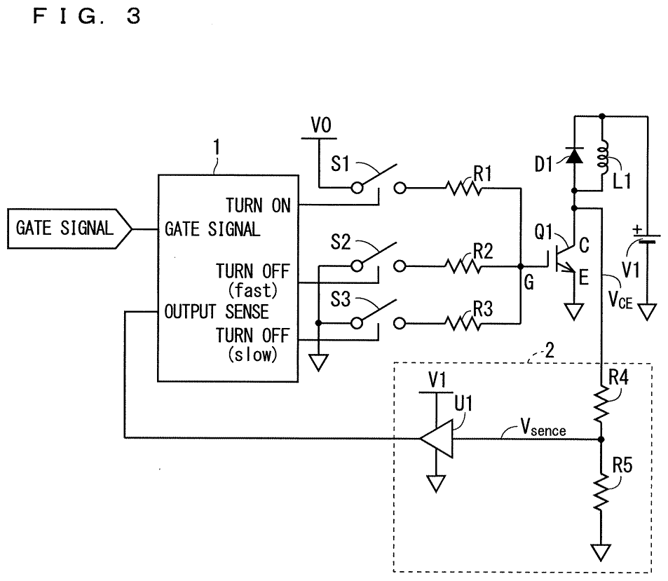

FIG. 3 is a circuit diagram illustrating a configuration of a semiconductor switching element drive circuit according to a second embodiment. The semiconductor switching element drive circuit according to the second embodiment and the semiconductor switching element drive circuit according to the first embodiment are different from each other in the configuration of the output voltage detection unit 2.

An output voltage detection unit 2 according to the second embodiment includes voltage-dividing resistors R4 and R5 that generate a divided voltage (Vₛₑₙₛₑ) of an output voltage (V_{CE}) of the semiconductor switching element Q1, and a logic circuit U1 that generates a switching signal (V_{high}) based on the divided voltage (Vₛₑₙₛₑ).

In the second embodiment, the voltage-dividing resistors R4 and R5 include one or more thermistors provided in the vicinity of the semiconductor switching element Q1, and the one or more thermistors change the divided voltage (Vₛₑₙₛₑ) based on a switch temperature.

Note that it is only necessary that at least one of the voltage-dividing resistors R4 and R5 is a thermistor. For example, a PTC thermistor having positive temperature specification is used as the voltage-dividing resistor R4, and an NTC thermistor having negative temperature specification is used as the voltage-dividing resistor R5. Since the divided voltage (Vₛₑₙₛₑ) is expressed as V_{CE}×R5/(R4+R5), the divided voltage (Vₛₑₙₛₑ) decreases as the switch temperature increases when these thermistors are used in a case where the output voltage (V_{CE}) is the same. Accordingly, the output voltage (V_{CE}) for generating the switching signal by the output voltage detection unit 2 in a case where the switch temperature is the first temperature is larger than the output voltage (V_{CE}) for generating the switching signal by the output voltage detection unit 2 in a case where the switch temperature is the second temperature.

### <Summary of Second Embodiment>

According to the semiconductor switching element drive circuit of the second embodiment as described above, the output voltage detection unit 2 generates the switching signal based on the switch temperature and the output voltage (V_{CE}) of the semiconductor switching element Q1. The output voltage (V_{CE}) for generating the switching signal by the output voltage detection unit 2 in a case where the switch temperature is the first temperature is larger than the output voltage (V_{CE}) for generating the switching signal by the output voltage detection unit 2 in a case where the switch temperature is the second temperature. Therefore, the timing of decreasing the switching speed in a case where the switch temperature is the relatively high first temperature can be made later than the timing of decreasing the switching speed in a case where the switch temperature is the relatively low second temperature. As a result, effects similar to those of the first embodiment can be obtained.

Note that a resistance value of the PTC thermistor is substantially constant at about an ordinary temperature, but rapidly increases above a certain temperature. On the other hand, a resistance value of the NTC thermistor gradually increases as the temperature increases. Therefore, in a case where the NTC thermistor is used as the voltage-dividing resistor R5, it is easy to control the timing of decreasing the switching speed.

### Third Embodiment

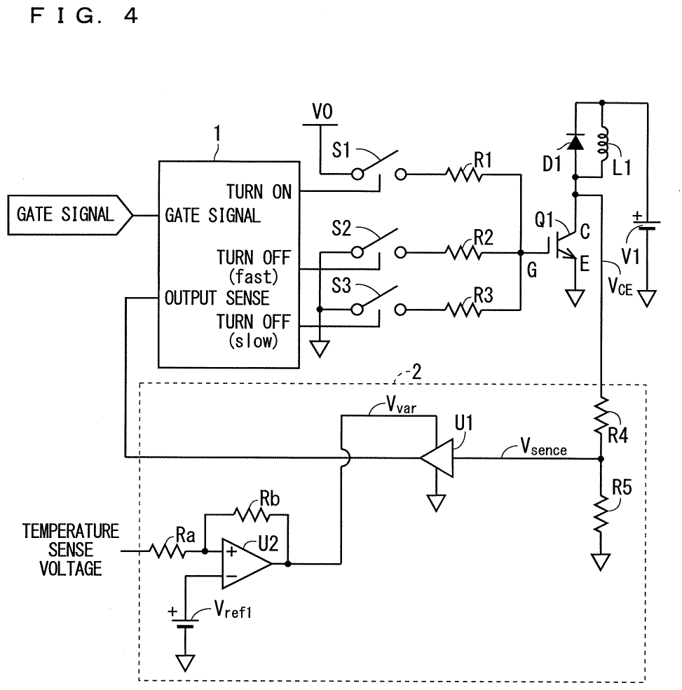

FIG. 4 is a circuit diagram illustrating a configuration of a semiconductor switching element drive circuit according to a third embodiment. The semiconductor switching element drive circuit according to the third embodiment and the semiconductor switching element drive circuit according to the first embodiment are different from each other in the configuration of the output voltage detection unit 2.

An output voltage detection unit 2 according to the third embodiment includes voltage-dividing resistors R4 and R5 that generate a divided voltage (Vₛₑₙₛₑ) of an output voltage (V_{CE}) of the semiconductor switching element Q1, a logic circuit U1 that generates a switching signal (V_{high}) based on the divided voltage (Vₛₑₙₛₑ), and an operational amplifier U2.

A temperature sense voltage corresponding to the switch temperature and having negative temperature characteristics and a first reference voltage (V_{ref1}) are input to the operational amplifier U2. The operational amplifier U2 to which resistors Ra and Rb are connected constitutes an inverting amplifier circuit, and an output (Vᵥₐᵣ) of the operational amplifier U2 is expressed by the above formula (1) using the first reference voltage (V_{ref1}) and the temperature sense voltage (Vₛ). As the switch temperature increases, the temperature sense voltage (Vₛ) decreases, and therefore the output (Vᵥₐᵣ) of the operational amplifier U2 that inverts the input increases as can be seen from the above formula (1).

In the third embodiment, the output (Vᵥₐᵣ) of the operational amplifier U2 is input to the logic circuit U1 instead of the power supply voltage. Therefore, a threshold value to be compared with the divided voltage (Vₛₑₙₛₑ) in the logic circuit U1 is controlled based on the output (Vᵥₐᵣ) of the operational amplifier U2. That is, the operational amplifier U2 controls the threshold value of the logic circuit U1 based on the temperature sense voltage.

With the above configuration, the threshold value of the logic circuit U1 is large in a case where the switch temperature is a relatively high first temperature, and the threshold value of the logic circuit U1 is small in a case where the switch temperature is a second temperature lower than the first temperature. Accordingly, the output voltage (V_{CE}) for generating the switching signal by the output voltage detection unit 2 in a case where the switch temperature is the first temperature is larger than the output voltage (V_{CE}) for generating the switching signal by the output voltage detection unit 2 in a case where the switch temperature is the second temperature.

### <Summary of Third Embodiment>

According to the semiconductor switching element drive circuit of the third embodiment as described above, the output voltage detection unit 2 generates the switching signal based on the switch temperature and the output voltage (V_{CE}) of the semiconductor switching element Q1. The output voltage (V_{CE}) for generating the switching signal by the output voltage detection unit 2 in a case where the switch temperature is the first temperature is larger than the output voltage (V_{CE}) for generating the switching signal by the output voltage detection unit 2 in a case where the switch temperature is the second temperature. Therefore, the timing of decreasing the switching speed in a case where the switch temperature is the relatively high first temperature can be made later than the timing of decreasing the switching speed in a case where the switch temperature is the relatively low second temperature. As a result, effects similar to those of the first embodiment can be obtained.

### Fourth Embodiment

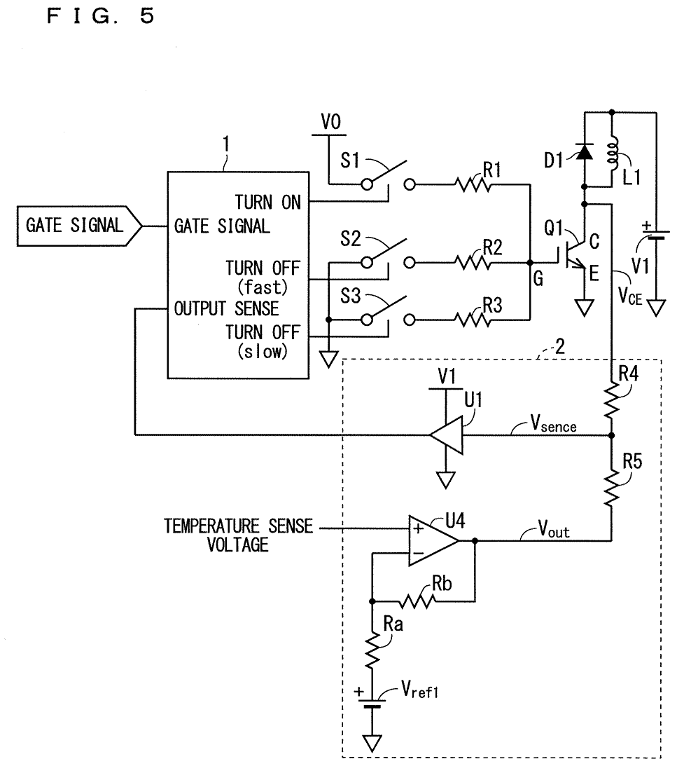

FIG. 5 is a circuit diagram illustrating a configuration of a semiconductor switching element drive circuit according to a fourth embodiment. The semiconductor switching element drive circuit according to the fourth embodiment and the semiconductor switching element drive circuit according to the first embodiment are different from each other in the configuration of the output voltage detection unit 2.

An output voltage detection unit 2 according to the fourth embodiment includes voltage-dividing resistors R4 and R5 that generate a divided voltage (Vₛₑₙₛₑ) of an output voltage (V_{CE}) of the semiconductor switching element Q1, a logic circuit U1 that generates a switching signal (V_{high}) based on the divided voltage (Vₛₑₙₛₑ), and an operational amplifier U4.

The operational amplifier U4 to which resistors Ra and Rb are connected and which is electrically connected to a first reference voltage (V_{ref1}) with the resistor Ra interposed therebetween constitutes a non-inverting amplifier circuit. A temperature sense voltage corresponding to a switch temperature and having negative temperature characteristics is input to a + input terminal of the operational amplifier U4. Accordingly, as the switch temperature increases, the temperature sense voltage (Vₛ) decreases, and the output (Vₒᵤₜ) of the operational amplifier U4 that does not invert the input decreases.

An output terminal of the operational amplifier U4 is connected to the other end of the voltage-dividing resistor R5 that is different from one end connected to the voltage-dividing resistor R4. Thus, the divided voltage (Vₛₑₙₛₑ) is expressed by the following formula (2) using an output voltage (V_{CE}) of the semiconductor switching element Q1 and the output (Vₒᵤₜ) of the operational amplifier U4. The second term on the right side of the following formula (2) represents an offset voltage for offsetting the divided voltage (Vₛₑₙₛₑ), and is expressed by the output (Vₒᵤₜ) of the operational amplifier U4. Therefore, the operational amplifier U4 according to the fourth embodiment generates the offset voltage for offsetting divided voltage (Vₛₑₙₛₑ) based on the temperature sense voltage.

$$[ Mathematical formula 2 ]$$

$${V}_{sense} = \frac{R 5}{R 4 + R 5} {V}_{CE} + \frac{R 5}{R 4 + R 5} {V}_{out} \qquad ( 2 )$$

As the switch temperature increases, the output (Vₒᵤₜ) of the operational amplifier U4 decreases, and therefore the divided voltage (Vₛₑₙₛₑ) of the formula (2) decreases. Accordingly, the output voltage (V_{CE}) for generating the switching signal by the output voltage detection unit 2 in a case where the switch temperature is the first temperature is larger than the output voltage (V_{CE}) for generating the switching signal by the output voltage detection unit 2 in a case where the switch temperature is the second temperature.

### <Summary of Fourth Embodiment>

According to the semiconductor switching element drive circuit of the fourth embodiment as described above, the output voltage detection unit 2 generates the switching signal based on the switch temperature and the output voltage (V_{CE}) of the semiconductor switching element Q1. The output voltage (V_{CE}) for generating the switching signal by the output voltage detection unit 2 in a case where the switch temperature is the first temperature is larger than the output voltage (V_{CE}) for generating the switching signal by the output voltage detection unit 2 in a case where the switch temperature is the second temperature. Therefore, the timing of decreasing the switching speed in a case where the switch temperature is the relatively high first temperature can be made later than the timing of decreasing the switching speed in a case where the switch temperature is the relatively low second temperature. As a result, effects similar to those of the first embodiment can be obtained.

Note that a capacitor may be provided between the voltage-dividing resistor R5 and a ground potential on the operational amplifier U4 side. According to such a configuration, resistance to external noise can be enhanced.

### <Modification>

The first reference voltage (V_{ref1}) in the first, third, and fourth embodiments may be a voltage of a variable power supply. According to such a configuration, it is possible to correct deviation of the divided voltage, deviation of the threshold value of the logic circuit U1, and deviation of the temperature sense voltage that occur due to manufacturing variations. Furthermore, in a case where the first reference voltage (V_{ref1}) is fixed, even if the threshold value of the logic circuit U1 is deviated, the deviation of the divided voltage or the like can be adjusted by a ratio of resistance values of the voltage-dividing resistors R4 and R5 by using variable resistors or the like as the voltage-dividing resistors R4 and R5. Note that a trigger voltage (V_{trigger}), which is a divided voltage of the output voltage (V_{CE}) for generating the switching signal by the logic circuit U1, is expressed by the following formula (3) using a threshold value (U1ₜₕ) of the logic circuit U1.

$$[ Mathematical formula 3 ]$$

$${V}_{trriger} = \frac{R 4 + R 5}{R 5} U {1}_{th} \qquad ( 3 )$$

For example, in a case where the resistance value of the voltage-dividing resistor R4 is 100 kΩ and the resistance value of the voltage-dividing resistor R5 is 1 kΩ, it is only necessary to decrease the resistance value of the voltage-dividing resistor R4 by x ratio in a case where the threshold value (U1ₜₕ) increases by x ratio since R4>>R5. Note that the voltage-dividing resistors R4 and R5 may include one or more variable resistors so that such adjustment can be made.

The embodiments and modifications can be freely combined and changed or omitted as appropriate.

### EXPLANATION OF REFERENCE SIGNS

1: control unit
2: output voltage detection unit
6: change unit
R4, R5: voltage-dividing resistor
Q1: semiconductor switching element
U1: logic circuit
U2, U4: operational amplifier
U3: comparator

1. A semiconductor switching element drive circuit that drives a gate of a semiconductor switching element, the semiconductor switching element drive circuit comprising:
a control circuitry that switches a switching speed during turn-off operation of the semiconductor switching element based on a switching signal; and
an output voltage detection circuitry that generates the switching signal based on a temperature related to the semiconductor switching element and an output voltage of the semiconductor switching element,
wherein the output voltage for generating the switching signal by the output voltage detection circuitry in a case where the temperature is a first temperature is larger than the output voltage for generating the switching signal by the output voltage detection circuitry in a case where the temperature is a second temperature lower than the first temperature.

2. The semiconductor switching element drive circuit according to claim 1, wherein the output voltage detection circuitry includes
a voltage-dividing resistor that generates a divided voltage of the output voltage,
a logic circuit that generates the switching signal based on the divided voltage,
an operational amplifier to which a temperature sense voltage corresponding to the temperature and having negative temperature characteristics and a first reference voltage are input,
a comparator to which an output of the operational amplifier and a second reference voltage are input, and
a change circuitry that changes the divided voltage by changing a resistance value of the voltage-dividing resistor based on an output of the comparator.

3. The semiconductor switching element drive circuit according to claim 1, wherein the output voltage detection circuitry includes
a voltage-dividing resistor that generates a divided voltage of the output voltage, and
a logic circuit that generates the switching signal based on the divided voltage, and
the voltage-dividing resistor includes one or more thermistors that change the divided voltage based on the temperature.

4. The semiconductor switching element drive circuit according to claim 1, wherein the output voltage detection circuitry includes
a voltage-dividing resistor that generates a divided voltage of the output voltage,
a logic circuit that generates the switching signal based on the divided voltage and a threshold value, and
an operational amplifier that controls the threshold value of the logic circuit based on a temperature sense voltage corresponding to the temperature and having negative temperature characteristics and to which a first reference voltage is input.

5. The semiconductor switching element drive circuit according to claim 1, wherein the output voltage detection circuitry includes
a voltage-dividing resistor that generates a divided voltage of the output voltage,
a logic circuit that generates the switching signal based on the divided voltage, and
an operational amplifier that generates an offset voltage for offsetting the divided voltage based on a temperature sense voltage corresponding to the temperature and having negative temperature characteristics and that is electrically connected to a first reference voltage.

6. The semiconductor switching element drive circuit according to claim 2, wherein the first reference voltage is a voltage of a variable power supply.

7. The semiconductor switching element drive circuit according to claim 4, wherein the first reference voltage is a voltage of a variable power supply.

8. The semiconductor switching element drive circuit according to claim 5, wherein the first reference voltage is a voltage of a variable power supply.
